(19) United States
(12) Patent Application Publication
(10) Pub. No.: US 2026/0136851 A1
(43) Pub. Date: May 14, 2026

(54) REPAIRING LOW-K MATERIALS WITH SILICON-FREE TREATMENT PRECURSORS TO PREVENT SILICON RESIDUE FORMATION

(71) Applicant: Applied Materials, Inc., Santa Clara, CA (US)

(72) Inventors: Jingyi Sui, Evanston, IL (US); Xinyi Lu, Santa Clara, CA (US); Bo Xie, San Jose, CA (US); Chi-I Lang, Cupertino, CA (US); Li-Qun Xia, Cupertino, CA (US)

(73) Assignee: Applied Materials, Inc., Santa Clara, CA (US)

(21) Appl. No.: 18/944,511

(22) Filed: Nov. 12, 2024

(51) Int. Cl. H01L 21/02; H01L 21/67

(52) U.S. Cl. CPC H10P 14/6336; H10P 14/6902; H10P 14/6939; H10P 72/0436; H10P 72/0602

(57) ABSTRACT

Exemplary methods of semiconductor processing may include providing a silicon-free treatment precursor to a processing region of a semiconductor processing chamber. A substrate may be housed within the processing region. An exposed region of a silicon-containing material and an exposed region of a metal-containing material may be disposed on the substrate. The methods may include contacting the substrate with the silicon-free treatment precursor. The contacting may reduce a dielectric constant of the silicon-containing material. Subsequent to contacting the substrate with the silicon-free treatment precursor, a surface of the metal-containing material may be silicon-free.

### TECHNICAL FIELD

The present technology relates to methods and systems for semiconductor processing. More specifically, the present technology relates to methods for preventing silicon-containing residues after integration and/or repair operations.

### BACKGROUND

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. Materials used to form layers of materials may affect operational characteristics of the devices produced. As material thicknesses continue to reduce, characteristics of the films may have a greater impact on device performance.

Thus, there is a need for improved systems and methods that can be used to produce high quality devices and structures. These and other needs are addressed by the present technology.

### SUMMARY

Exemplary methods of semiconductor processing may include providing a silicon-free treatment precursor to a processing region of a semiconductor processing chamber. A substrate may be housed within the processing region. An exposed region of a silicon-containing material and an exposed region of a metal-containing material may be disposed on the substrate. The methods may include contacting the substrate with the silicon-free treatment precursor. The contacting may reduce a dielectric constant of the silicon-containing material. Subsequent to contacting the substrate with the silicon-free treatment precursor, a surface of the metal-containing material may be silicon-free.

In embodiments, the silicon-free treatment precursor may be or include a carbon-containing precursor. A flow rate of the silicon-free treatment precursor may be greater than or about 100 mgm. A metal of the metal-containing material may be or include copper (Cu), cobalt (Co), nickel (Ni), aluminum (Al), ruthenium (Ru), molybdenum (Mo), or tungsten (W). The methods may include prior to providing the silicon-free treatment precursor to the processing region of the semiconductor processing chamber, removing an etch stop layer overlying the metal-containing material. The silicon-containing material may further include oxygen, carbon, hydrogen, or a combination thereof. The methods may further include exposing the substrate to ultraviolet (UV) radiation while or subsequent to contacting the substrate with the silicon-free treatment precursor. Subsequent to contacting the substrate with the silicon-free treatment precursor, the dielectric constant of the silicon-containing material may be less than or about 3.0. A temperature within the processing region may be maintained at greater than or about 75° C. A pressure within the processing region may be maintained at less than or about 15 Torr.

Some embodiments of the present technology may encompass semiconductor processing methods. The methods may include providing a silicon-free treatment precursor to a processing region of a semiconductor processing chamber. A substrate may be housed within the processing region. An exposed region of a silicon-containing material and an exposed region of a metal-containing material may be disposed on the substrate. The methods may include contacting the substrate with the silicon-free treatment precursor. The contacting may increase an amount of methyl groups (—CH₃) in the silicon-containing material. Subsequent to contacting the substrate with the silicon-free treatment precursor, a surface of the metal-containing material may be silicon-free.

In some embodiments, the silicon-free treatment precursor may be or include a carbon-containing precursor. The silicon-free treatment precursor may include a carbon-oxygen double bond, a carbon-carbon double bond, or a carbon-carbon triple bond. A metal of the metal-containing material may be or include copper (Cu), cobalt (Co), nickel (Ni), aluminum (Al), ruthenium (Ru), molybdenum (Mo), or tungsten (W). The methods may include exposing the substrate to ultraviolet (UV) radiation while or subsequent to contacting the substrate with the silicon-free treatment precursor. Contacting the substrate with the silicon-free treatment precursor may increase a hydrophobicity of the silicon-containing material. Contacting the substrate with the silicon-free treatment precursor may reduce a dielectric constant of the silicon-containing material by greater than or about 10%. Contacting the substrate with the silicon-free treatment precursor may be performed for a period of time of less than or about 15 minutes. A temperature within the processing region may be maintained at greater than or about 75° C. A pressure within the processing region may be maintained at greater than or about 1 Torr.

Such technology may provide numerous benefits over conventional systems and techniques. For example, embodiments of the present technology may increase carbon concentrations, such as an amount of methyl groups (—CH₃) and therefore reduce dielectric constant, in materials that have been carbon depleted, such as during integration operations. Additionally, the present technology may prevent a presence of residue on exposed metal-containing materials subsequent to increasing carbon concentrations in the materials that have been carbon depleted. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

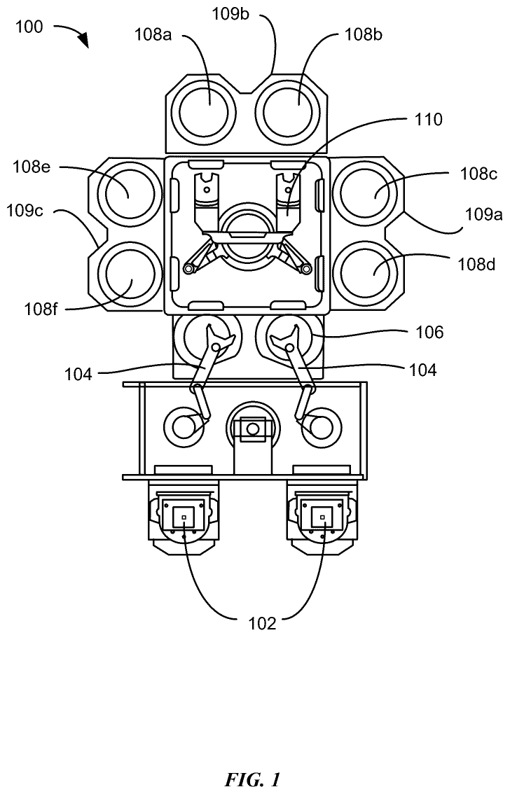

FIG. 1 shows a top plan view of an exemplary processing system according to some embodiments of the present technology.

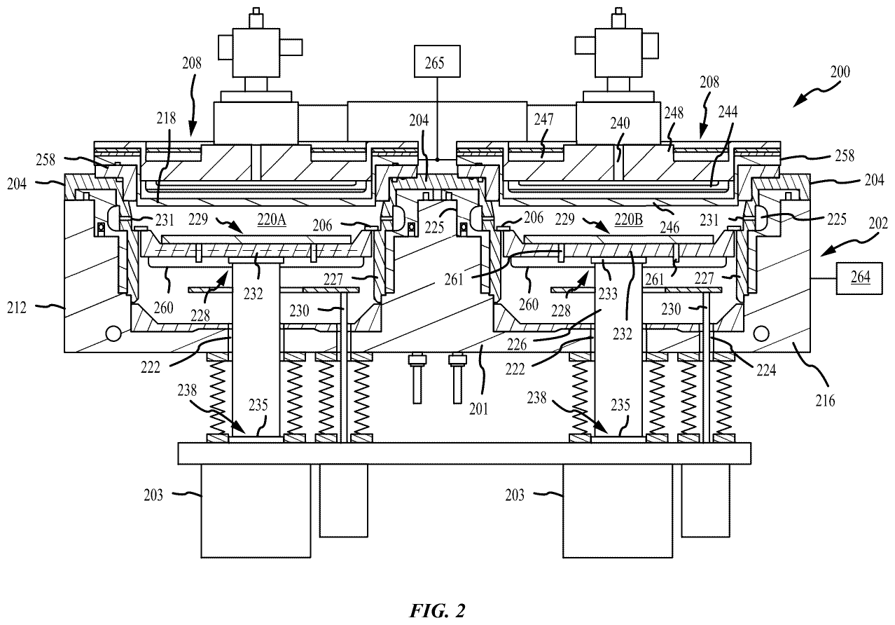

FIG. 2 shows a schematic cross-sectional view of an exemplary plasma deposition system according to some embodiments of the present technology.

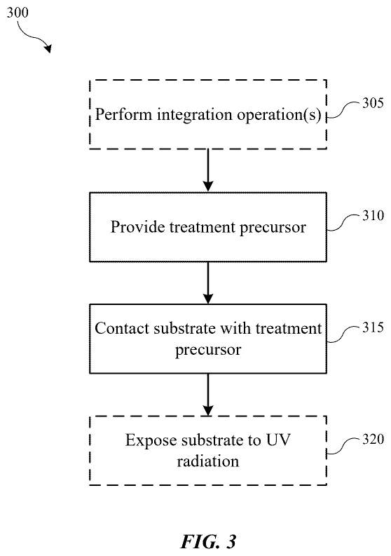

FIG. 3 shows operations in a semiconductor processing method according to some embodiments of the present technology.

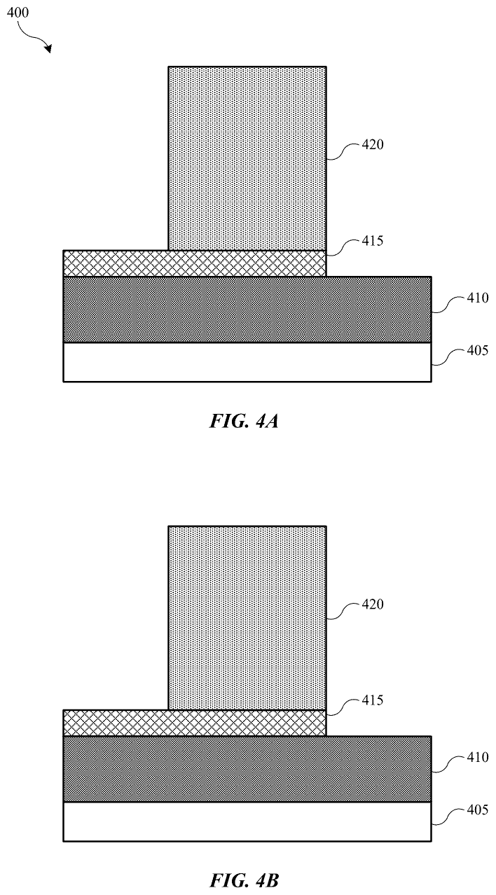

FIGS. 4A-4B show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor device sizes continue to reduce, the constituent films included within a structure may affect device performance, as well as fabrication of other materials being included in the device. Additionally, as demand increases, throughput and queue times become a point of emphasis. Thus, a demand exists for high-quality materials and structures that may be formed both quickly and efficiently. In processes to form conformal low dielectric constant silicon-containing materials, such as in gate all around (GAA) applications, increasingly low dielectric constants may be desired. However, various integration operations may reduce the dielectric constant, such as by introducing hydroxyl groups (—OH) to the material. Due to the introduction of hydroxyl groups (—OH) and resultant depletion of carbon in the silicon-containing materials during integration operations, the dielectric constant of the silicon-containing material may be undesirably increased and may be too high for certain transistors, such as GAA transistors.

To address dielectric constant issues, conventional approaches have addressed the introduction of hydroxyl groups (—OH) and resultant depletion of carbon in the silicon-containing materials during integration operations by further reducing the dielectric constant of the as-deposited dielectric material. However, these conventional approaches may not be able to meet the requirements of certain transistors, such as GAA transistors.

The present technology overcomes these issues by treating the silicon-containing material subsequent to integration operations. The treatment may reintroduce carbon, such as methyl group (—CH₃) to the carbon depleted material. This may also increase a hydrophobicity of the silicon-containing material. However, unlike some treatments, which may utilize a silicon-containing precursor and introduce a silicon-containing residue to the structure, the present technology may utilize a silicon-free treatment precursor. The silicon-free treatment precursor may still be able to repair the damaged silicon-containing material. Conversely, the silicon-free treatment precursor may not form a silicon-containing residue. This may avoid the need to remove silicon-containing residue from the structure.

Although the remaining disclosure will routinely identify specific processes utilizing the disclosed technology, it will be readily understood that the systems and methods are equally applicable to other processes as may occur in the described chambers or any other chamber. Accordingly, the technology should not be considered to be so limited as for use with these specific processes or chambers alone. The disclosure will discuss one set of possible chambers that may be used to perform processes according to embodiments of the present technology before additional variations and adjustments to this system according to embodiments of the present technology are described.

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

FIG. 3 shows exemplary operations in a semiconductor processing method 300 according to some embodiments of the present technology. The method may be performed in a variety of processing chambers, including system 200 described above. Method 300 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

Method 300 may involve optional operations to develop the semiconductor structure to a particular fabrication operation. Although in some embodiments method 300 may be performed on a base structure, in some embodiments the method may be performed subsequent other material formation or removal. For example, any number of deposition, masking, or removal operations may be performed to produce any transistor, memory, or other structural aspects on a substrate. The substrate may be disposed on a substrate support, which may be positioned within a processing region of a semiconductor processing chamber. The operations may be performed in the same chamber in which aspects of method 300 may be performed, and one or more operations may also be performed in one or more chambers on a similar platform as a chamber in which operations of method 300 may be performed, or on other platforms. Method 300 describes the operations shown schematically in FIGS. 4A-4B, the illustrations of which will be described in conjunction with the operations of method 300. It is to be understood that FIGS. 4A-4B illustrate only partial schematic views, and a substrate may contain any number of transistor sections having aspects as illustrated in the figures.

As shown in FIG. 4A, structure 400 may include a substrate 405. One or more layers of material may be formed over the substrate 405. For example, a metal-containing material 410 may be disposed on the substrate 405. An etch stop layer 415 may be overly at least a portion of the metal-containing layer 410. A silicon-containing material 420 may overly at least a portion of the etch stop layer 415. A first surface of the etch stop layer 410 may be in contact with the metal-containing layer 410. A second surface of the etch stop layer 410 opposite the first surface may be in contact with the silicon-containing material 420. As illustrated on the left portion of FIG. 4A, the etch stop layer 415 may extend across and cover the underlying metal-containing layer 410. Conversely, as illustrated on the right portion of FIG. 4A, the etch stop layer 415 may be patterned and remove to at least expose the underlying metal-containing layer 410. As such, an exposed region of the silicon-containing material 420 and an exposed region of the metal-containing material 410 may be disposed on the substrate 405. As such, some embodiments may include, prior to treating the silicon-containing material 420, removing the etch stop layer 415 overlying the metal-containing material 410.

The substrate 405 may be made of or contain silicon, germanium, a combination of silicon and germanium, or some other semiconductor substrate material. The metal-containing material 410 may be a metal, a metal-and-oxygen-containing material, or any other metal-containing material. In embodiments, the metal may be or include, but is not limited to, copper (Cu), cobalt (Co), nickel (Ni), aluminum (Al), ruthenium (Ru), molybdenum (Mo), tungsten (W), or any other metal used or useful in semiconductor processing. The etch stop layer 415 may be or include, but is not limited to, a silicon-containing material (e.g., silicon-and-nitrogen-containing material, silicon-and-oxygen-containing material, silicon-and-carbon-containing material, silicon-carbon-and-nitrogen-containing material, silicon-oxygen-and-nitrogen-containing material, etc.), an aluminum-containing material (e.g., aluminum-and-oxygen-containing material or aluminum-and-nitrogen-containing material), a boron-containing material (e.g., boron-and-nitrogen-containing material), a combination of these materials, such as a multi-layered stack of materials, or any other etch stop layer materials used or useful in semiconductor processing.

The silicon-containing material 420 may be a dielectric material, and may include oxygen, nitrogen, carbon, hydrogen, a combination thereof, or other constituents in addition to silicon. For example, the silicon-containing material 420 may be or include a silicon-and-oxygen-containing material, a silicon-and-nitrogen-containing material, a silicon-and-carbon-containing material. For the etch stop layer 415 to be effective, the silicon-containing material 420 may be different from the etch stop layer 415, such that an etch may slow down or stop when etching through the silicon-containing material 420 and to the etch stop layer 415. The silicon-containing material 420 may be characterized by a first dielectric constant of less than or about 3.2, and may be characterized by a dielectric constant of less than or about 3.15, less than or about 3.1, less than or about 3.05, less than or about 3.0, less than or about 2.95, less than or about 2.9, less than or about 2.85, less than or about 2.8, less than or about 2.75, less than or about 2.7, less than or about 2.65, less than or about 2.6, less than or about 2.55, less than or about 2.5, or less.

At optional operation 305, method 300 may include performing one or more integration operations. The integration operations may include, but are not limited to, an etching operation, including a dry etching operation or wet etching operation, an ashing operation, or a cleaning operation. The one or more integration operations performed at optional operation 305 may damage the silicon-containing material 420. For example, the one or more integration operations performed at optional operation 305 may remove methyl groups (—CH₃) from the silicon-containing material 420 and increase hydroxyl groups (—OH) on a surface of the silicon-containing material 420. This may also decrease hydrophobicity and, therefore, increase hydrophilicity of the silicon-containing material 420.

Performing the one or more integration operations at optional operation 305 may increase the dielectric constant of the silicon-containing material 420. In embodiments, the one or more integration operations performed at optional operation 305 may increase the dielectric constant of the silicon-containing material 420 to a second dielectric constant that is greater than the first dielectric constant. The dielectric constant of the silicon-containing material 420 may be increased by greater than or about 0.1, and may be increased by greater than or about 0.15, greater than or about 0.2, greater than or about 0.25, greater than or about 0.3, greater than or about 0.35, greater than or about 0.4, greater than or about 0.45, greater than or about 0.5, or more.

At operation 310, method 300 may include providing a silicon-free treatment precursor to the processing region of the semiconductor processing chamber. The silicon-free treatment precursor may be a hydrogen-containing precursor. For example the silicon-free treatment precursor may be diatomic hydrogen (H₂) or ammonia (NH₃). The silicon-free treatment precursor may also be a carbon-containing precursor, such as a silicon-free carbon-containing precursor. As such, the silicon-free treatment precursor may be any precursor including carbon and may also include oxygen and/or hydrogen. The silicon-free treatment precursor may include a carbon-oxygen double bond, a carbon-carbon double bond, or a carbon-carbon triple bond. In embodiments, both a silicon-free hydrogen-containing precursor and a silicon-free carbon-containing precursor may be provided as the silicon-free treatment precursor. The hydrogen-containing precursor and the carbon-containing precursor may be provided simultaneously or sequentially.

Silicon-free treatment precursors may be any precursor from Group I-VI below:

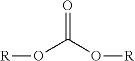

Group I. Each R may be independently selected from hydrogen (H), an alkane, an alkene, an alkyne, or an aryl. The alkane, the alkene, the alkyne, and the aryl may have between one and twenty carbons.

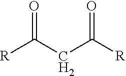

Group II. Each R may be independently selected from an alkane, an alkene, or an alkyne. The alkane, the alkene, and the alkyne may have between one and twenty carbons.

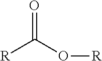

Group III. Each R may be independently selected from hydrogen (H), an alkane, an alkene, an alkyne, or an aryl. The alkane, the alkene, the alkyne, and the aryl may have between one and twenty carbons.

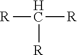

Group IV. Each R may be independently selected from hydrogen (H), an alkane, an alkene, an alkyne, or an aryl. The alkane, the alkene, the alkyne, and the aryl may have between one and twenty carbons.

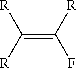

Group V. Each R may be independently selected from hydrogen (H), an alkane, an alkene, an alkyne, or an aryl. The alkane, the alkene, the alkyne, and the aryl may have between one and twenty carbons.

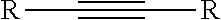

Group VI. Each R may be independently selected from hydrogen (H), an alkane, an alkene, an alkyne, or an aryl. The alkane, the alkene, the alkyne, and the aryl may have between one and twenty carbons.

A flow rate of the silicon-free treatment precursor may be adequate to interact with and treat the silicon-containing material 420. In embodiments, the flow rate of the silicon-free treatment precursor may be greater than or about 100 mgm, and may be greater than or about 200 mgm, greater than or about 300 mgm, greater than or about 400 mgm, greater than or about 500 mgm, greater than or about 750 mgm, greater than or about 1,000 mgm, greater than or about 1,250 mgm, greater than or about 1,500 mgm, greater than or about 1,750 mgm, greater than or about 2,000 mgm, or more. At lower flow rates, a longer treatment time may be needed to fully treat the silicon-containing material 420, which may reduce throughput. The silicon-free treatment precursor may be provided in vapor phase, which may allow the silicon-free treatment precursor to penetrate deeply into the silicon-containing material 420. The vaporized silicon-free treatment precursor may be vaporized prior to being provided to the processing region at operation 310 or may be vaporized in the processing region.

Operation 310 may or may not include delivery of additional precursors, such as one or more carrier gases to assist the flow of the silicon-free treatment precursor. The carrier gases may include helium, argon, or diatomic nitrogen.

In embodiments, method 300 may include generating a plasma of the silicon-free treatment precursor. The plasma effluents of the silicon-free treatment precursor may be generated at a plasma power of less than or about 3,000 W, and may be generated at a plasma power of less than or about 2,750 W, less than or about 2,500 W, less than or about 2,250 W, less than or about 2,000 W, less than or about 1,750 W, less than or about 1,500 W, less than or about 1,250 W, less than or about 1,000 W, less than or about 750 W, less than or about 500 W, less than or about 250 W, or less. While a plasma of the silicon-free treatment precursor may be generated in some embodiments, other embodiments may include a thermal process that does not include generating a plasma of the silicon-free treatment precursor.

At operation 315, method 300 may include contacting the substrate 405, including the silicon-containing material 420 and/or the metal-containing material 410, with the silicon-free treatment precursor or the plasma effluents thereof. When the silicon-free treatment precursor comprises a hydrogen-containing precursor, the hydrogen may reduce the metal-containing material 410 from a metal-and-oxygen-containing material to a metal-containing material. That is, the contacting may reduce and/or remove a native oxide formed on the metal-containing material 410. When the silicon-free treatment precursor comprises a carbon-containing precursor, the contacting may increase an amount of methyl groups (—CH₃) in the silicon-containing material 420. That is, the contacting may reduce silanol groups (Si—OH) and/or terminal hydroxyl groups (—OH) in the silicon-containing material 420, such as through the replacement of silanol groups (Si—OH) and/or terminal hydroxyl groups (—OH) with methyl group (—CH₃). The contacting may also increase a hydrophobicity of the silicon-containing material 420. Therefore, the contacting may repair the silicon-containing material 420 that was damaged during optional operation 305. Additionally and/or alternatively, even when optional operation 305 may not be performed, the contacting at operation 315 may nevertheless further reduce the dielectric constant of the silicon-containing material by increases the amount of methyl group (—CH₃).

The contacting at operation 320 may reduce the dielectric constant to a third dielectric constant that is less than the second dielectric constant. The third dielectric constant may be less than, equal to, or greater than the first dielectric constant. In embodiments, the third dielectric constant may be less than or about less than or about 3.0, and may be less than or about 2.95, less than or about 2.9, less than or about 2.85, less than or about 2.8, less than or about 2.75, less than or about 2.7, less than or about 2.65, less than or about 2.6, less than or about 2.55, less than or about 2.5, or less. In embodiments, contacting the substrate 405, including the silicon-containing material 420, with the silicon-free treatment precursor may reduce the dielectric constant of the silicon-containing material 420 by greater than or about 10%, and may reduce the dielectric constant by greater than or about 11%, greater than or about 12%, greater than or about 13%, greater than or about 14%, greater than or about 15%, or more.

In embodiments, contacting the substrate 405, including the silicon-containing material 420, with the silicon-free treatment precursor may be performed for a period of time of less than or about 15 minutes. While the period of time may be partially dependent on the flow rate of the silicon-free treatment precursor, adequate flow rates may allow the period of time to be less than or about 14 minutes, such as less than or about 13 minutes, less than or about 12 minutes, less than or about 11 minutes, less than or about 10 minutes, less than or about 9 minutes, less than or about 8 minutes, less than or about 7 minutes, less than or about 6 minutes, less than or about 5 minutes, less than or about 4 minutes, less than or about 3 minutes, less than or about 2 minutes, less than or about 1 minute, less than or about 50 seconds, less than or about 40 seconds, less than or about 30 seconds, or less. The period of time may also be maintained at any period of time within these ranges, within smaller ranges encompassed by these ranges, or between any of these ranges.

At optional operation 320, method 300 may include exposing the substrate 405 to ultraviolet (UV) radiation. The UV radiation source may be, for example, a UV lamp. The UV radiation source may be positioned outside of the semiconductor processing chamber, and the semiconductor processing chamber may have a quartz window through which UV radiation may pass. The structure 400 may be positioned in an inert gas environment, such as, for example, helium, argon, or diatomic nitrogen. The processing semiconductor chamber may include a microwave source to heat the silicon-containing material 420 prior to or concurrently with contacting the silicon-containing material 420 with UV radiation. In embodiments, the UV radiation exposure may be conducted using a plasma to simulate UV radiation wavelengths. The plasma may be formed by coupling RF power to a treatment gas such as, for example, helium, argon, molecular oxygen, or diatomic oxygen. Exposing the silicon-containing material 420 to UV radiation may break Si—H and/or SI—OH bonds in the material, allowing Si—CH₂—CH₂—Si(CH₃)₃ and/or Si—O—Si(CH₃)₃ bonds to form, thereby increasing the carbon concentration, such as the methyl (—CH₃) concentration, and reducing the dielectric constant.

During optional operation 320, conditions of the UV radiation may be tailored to treat the silicon-containing material 420. For example, a UV irradiance power may be characterized by between about 100 W/m² and about 2000 W/m². At UV irradiance powers less than 100 W/m², the UV radiation may not be significant enough to modify the material. At UV irradiance powers greater than 2000 W/m², the UV radiation may damage the material or structure. Additionally, a UV wavelength may be characterized by between about 100 nm and about 400 nm. A UV wavelength below 100 nm may require a special light source that may not be commonly available. A UV wavelength above 400 nm, such as visible light, may not have sufficient energy to modify the previously discussed bonds.

In embodiments, contacting the silicon-containing material 420 with the silicon-free treatment precursor and exposing the substrate to UV radiation may be performed simultaneously. Specifically, operation 315 and optional operation 320 may be performed simultaneously to treat the silicon-containing material 420. However, it is still contemplated that the operations may be performed in sequence in some embodiments with either operation 315 or optional operation 320 occurring first.

In embodiments, method 300 may include contacting the substrate 405, including the silicon-containing material 420 and/or the metal-containing material 410, with a single silicon-free treatment precursor, with or without UV exposure. Additionally, in some embodiments, the substrate 405 may first be contacted with the silicon-free hydrogen-containing precursor, which may be referred to as a first silicon-free treatment precursor, which may reduce the metal-containing material 410 or remove a native oxide from the metal-containing material 410. Subsequent to contacting the substrate 405 with the first silicon-free treatment precursor, the substrate 405 being contacted with the silicon-free carbon-containing precursor, which may be referred to as the second silicon-free treatment precursor, to treat the silicon-containing material 420.

As illustrated in FIG. 4B, the contacting at operation 315, with or without UV exposure at optional operation 320, may not form silicon-containing residue on the structure, including the metal-containing material 410. Through the use of silicon-free treatment precursors, formation of silicon-containing residue, such as on the metal-containing material 410, may be prevented. In technologies using treatment precursors that include silicon, silicon-containing residue may form on the substrate 405, such as on a surface of the metal-containing material 410. The silicon-containing residue may potentially impact via resistance and degrade performance of a final device.

The present technology may result in a metal-containing layer 410, subsequent to contacting the substrate with the silicon-free treatment precursor, having a surface characterized by a silicon concentration of less than or about 3 at. %, such as less than or about 2.8 at. %, less than or about 2.6 at. %, less than or about 2.4 at. %, less than or about 2.2 at. %, less than or about 2.0 at. %, less than or about 1.8 at. %, less than or about 1.6 at. %, less than or about 1.4 at. %, less than or about 1.2 at. %, less than or about 1.0 at. %, less than or about 0.8 at. %, less than or about 0.6 at. %, less than or about 0.4 at. %, less than or about 0.2 at. %, about 0.0 at. %, or a surface that is substantially free or even silicon-free. Silicon-free may refer to a surface that is entirely free of silicon.

Process conditions may impact the operations performed in method 300. Each of the operations of method 300 may be performed during a constant temperature in embodiments, while in some embodiments the temperature may be adjusted during different operations. In some embodiments of the present technology, method 300 may be performed at substrate, pedestal, and/or chamber temperatures greater than or about 75° C., and may greater than or about 100° C., greater than or about 150° C., greater than or about 200° C., greater than or about 250° C., greater than or about 300° C., greater than or about 350° C., greater than or about 400° C., greater than or about 450° C., greater than or about 500° C., or higher. At lower temperatures, there may not be sufficient energy to drive a reaction between the silicon-free treatment precursor and the silicon-containing material 420. However, higher temperatures may exceed a thermal budget of the structure 400. As such, method 300 may be performed at substrate, pedestal, and/or chamber temperatures less or about 500° C., and may be performed at temperatures less than or about 475° C., less than or about 450° C., less than or about 425° C., less than or about 400° C., less than or about 375° C., less or about 350° C., less or about 325° C., less or about 300° C., less or about 275° C., less or about 250° C., less or about 200° C., less or about 150° C., less or about 100° C., or lower. The temperature may also be maintained at any temperature within these ranges, within smaller ranges encompassed by these ranges, or between any of these ranges.

The pressure within the semiconductor processing chamber may also affect the operations performed. In embodiments, the pressure may be maintained at less than about 100 Torr. Accordingly, method 300 may be maintained at less than or about 90 Torr, and may be maintained at less than or about 80 Torr, less than or about 70 Torr, less than or about 60 Torr, less than or about 50 Torr, less than or about 40 Torr, less than or about 30 Torr, less than or about 25 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, less than or about 1 Torr, or less. Additionally, the pressure may be maintained at greater than or about 1 Torr, such as greater than or about 2 Torr, greater than or about 3 Torr, greater than or about 4 Torr, greater than or about 5 Torr, greater than or about 6 Torr, greater than or about 7 Torr, greater than or about 8 Torr, greater than or about 9 Torr, greater than or about 10 Torr, or more. The pressure may also be maintained at any pressure within these ranges, within smaller ranges encompassed by these ranges, or between any of these ranges.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-free treatment precursor to a processing region of a semiconductor processing chamber, wherein a substrate is housed within the processing region, and wherein an exposed region of a silicon-containing material and an exposed region of a metal-containing material are disposed on the substrate; and
contacting the substrate with the silicon-free treatment precursor, wherein the contacting reduces a dielectric constant of the silicon-containing material, and wherein, subsequent to contacting the substrate with the silicon-free treatment precursor, a surface of the metal-containing material is silicon-free.

2. The semiconductor processing method of claim 1, wherein the silicon-free treatment precursor comprises a carbon-containing precursor.

3. The semiconductor processing method of claim 1, wherein a flow rate of the silicon-free treatment precursor is greater than or about 100 mgm.

4. The semiconductor processing method of claim 1, wherein a metal of the metal-containing material comprises copper (Cu), cobalt (Co), nickel (Ni), aluminum (Al), ruthenium (Ru), molybdenum (Mo), or tungsten (W).

5. The semiconductor processing method of claim 1, further comprising:
prior to providing the silicon-free treatment precursor to the processing region of the semiconductor processing chamber, removing an etch stop layer overlying the metal-containing material.

6. The semiconductor processing method of claim 1, wherein the silicon-containing material further comprises oxygen, carbon, hydrogen, or a combination thereof.

7. The semiconductor processing method of claim 1, further comprising:
exposing the substrate to ultraviolet (UV) radiation while or subsequent to contacting the substrate with the silicon-free treatment precursor.

8. The semiconductor processing method of claim 1, wherein, subsequent to contacting the substrate with the silicon-free treatment precursor, the dielectric constant of the silicon-containing material is less than or about 3.0.

9. The semiconductor processing method of claim 1, wherein a temperature within the processing region is maintained at greater than or about 75° C.

10. The semiconductor processing method of claim 1, wherein a pressure within the processing region is maintained at less than or about 15 Torr.

11. A semiconductor processing method comprising:
providing a silicon-free treatment precursor to a processing region of a semiconductor processing chamber, wherein a substrate is housed within the processing region, and wherein an exposed region of a silicon-containing material and an exposed region of a metal-containing material are disposed on the substrate; and
contacting the substrate with the silicon-free treatment precursor, wherein the contacting increases an amount of methyl groups (—CH₃) in the silicon-containing material; and wherein, subsequent to contacting the substrate with the silicon-free treatment precursor, a surface of the metal-containing material is silicon-free.

12. The semiconductor processing method of claim 11, wherein the silicon-free treatment precursor comprises a carbon-containing precursor.

13. The semiconductor processing method of claim 11, wherein the silicon-free treatment precursor comprises a carbon-oxygen double bond, a carbon-carbon double bond, or a carbon-carbon triple bond.

14. The semiconductor processing method of claim 11, wherein a metal of the metal-containing material comprises copper (Cu), cobalt (Co), nickel (Ni), aluminum (Al), ruthenium (Ru), molybdenum (Mo), or tungsten (W).

15. The semiconductor processing method of claim 11, further comprising:
exposing the substrate to ultraviolet (UV) radiation while or subsequent to contacting the substrate with the silicon-free treatment precursor.

16. The semiconductor processing method of claim 11, wherein contacting the substrate with the silicon-free treatment precursor increases a hydrophobicity of the silicon-containing material.

17. The semiconductor processing method of claim 11, wherein contacting the substrate with the silicon-free treatment precursor reduces a dielectric constant of the silicon-containing material by greater than or about 10%.

18. The semiconductor processing method of claim 11, wherein contacting the substrate with the silicon-free treatment precursor is performed for a period of time of less than or about 15 minutes.

19. The semiconductor processing method of claim 11, wherein a temperature within the processing region is maintained at greater than or about 75° C.

20. The semiconductor processing method of claim 11, wherein a pressure within the processing region is maintained at greater than or about 1 Torr.
